(19) United States
(12) Patent Application Publication
(10) Pub. No.: US 2026/0068580 A1
(43) Pub. Date: Mar. 5, 2026

(54) BRUSH AND WAFER CLEANING DEVICE INCLUDING THE SAME

(71) Applicant: SAMSUNG ELECTRONICS CO., LTD., Suwon-si (KR)

(72) Inventors: Myeongjin LEE, Suwon-si (KR); Donghoon KWON, Suwon-si (KR)

(73) Assignee: SAMSUNG ELECTRONICS CO., LTD., Suwon-si (KR)

(21) Appl. No.: 19/057,315

(22) Filed: Feb. 19, 2025

(30) Foreign Application Priority Data
Sep. 4, 2024 (KR) 10-2024-0120018

(51) Int. Cl. H01L 21/67; A46B 9/00; A46B 13/00; A46B 13/02; A46D 1/00

(52) U.S. Cl. CPC H01L 21/67046; A46B 9/005; A46B 13/001; A46B 13/02; A46D 1/0207; A46B 2200/3073

(57) ABSTRACT

A brush includes a body, and a plurality of nodules disposed on at least one surface of the body and at least partially protruding outward from the body. The plurality of nodules include a plurality of first nodules. Each nodule of the plurality of first nodules includes a housing including an open side and an accommodating space, and a rotating ball including a portion accommodated inside the accommodating space of the housing and a remaining portion exposed to an outside of the housing. The rotating ball is rotatable.

### CROSS-REFERENCE TO RELATED APPLICATIONS

This application claims benefit of priority under 35 U.S.C. § 119 to Korean Patent Application No. 10-2024-0120018, filed on Sep. 4, 2024, in the Korean Intellectual Property Office, the disclosure of which is incorporated by reference herein in its entirety.

### BACKGROUND

### 1. Field

The present disclosure relates generally to semiconductor wafers, and more particularly, to a wafer cleaning brush and a wafer cleaning device including the same.

### 2. Description of Related Art

A process involving numerous steps may be performed to form a desired pattern on a semiconductor wafer. During such a process, an unnecessary thin film may form on the surface of the wafer and/or various contaminants may remain thereon. For example, when a polishing process (e.g., a planarization process) is carried out on a semiconductor wafer using a chemical-mechanical-polishing (CMP) device, polishing residues such as, but not limited to, colloidal polishing materials contained in a polishing slurry, may remain on the wafer. Therefore, a cleaning process may need to be performed to remove the polishing residues on the surface of the wafer before a subsequent process may be carried out.

Accordingly, a cleaning process may be performed to rotate and/or clean a wafer and/or a brush while the wafer and the brush are in contact with each other. As the cleaning process progresses, polishing residues may be moved to the brush, contaminating the brush. That is, the polishing residues attached to the brush may be moved to the wafer, which may cause reverse contamination of the wafer. In addition, during the cleaning process, while the brush eliminates the polishing residues on the wafer, the brush and/or the polishing residues may cause damage (e.g., scratches) to the surface of the wafer.

The above-described information is intended to enhance understanding of the background of the present disclosure, and may include information that may not make up the related art.

### SUMMARY

One or more example embodiments of the present disclosure provide a brush and a wafer cleaning device including the same to address the above-mentioned problems.

The problems to be addressed by the present disclosure may not be limited to those described above, and the following description of the present disclosure may allow a person having ordinary skill in the art to clearly understand other problems not mentioned above.

According to an aspect of the present disclosure, a brush includes a body, and a plurality of nodules disposed on at least one surface of the body and at least partially protruding outward from the body. The plurality of nodules include a plurality of first nodules. Each nodule of the plurality of first nodules includes a housing including an open side and an accommodating space, and a rotating ball including a portion accommodated inside the accommodating space of the housing and a remaining portion exposed to an outside of the housing. The rotating ball is rotatable.

According to an aspect of the present disclosure, a wafer cleaning device includes a brush, a brush driver configured to rotate the brush around a first rotation axis, and a wafer driver configured to rotate a wafer to be cleaned around a second rotation axis perpendicular to the first rotation axis. The brush includes a cylindrical body elongated in a direction parallel to the first rotation axis, and a plurality of nodules disposed on an outer surface of the cylindrical body and at least partially protruding outward from the cylindrical body. Each nodule of the plurality of nodules includes a housing including an open side and an accommodating space, and a rotating ball including a portion accommodated inside the accommodating space of the housing and a remaining portion exposed to the outside of the housing. The rotating ball is rotatable.

According to an aspect of the present disclosure, a wafer cleaning device includes a brush, a brush driver configured to rotate the brush around a first rotation axis, and a wafer driver configured to rotate a wafer to be cleaned around a second rotation axis parallel to the first rotation axis. The brush includes a disc-shaped body, and a plurality of nodules disposed on one side of the disc-shaped body and at least partially protruding outward from a side of the disc-shaped body. Each nodule of the plurality of nodules includes a housing including an open side and an accommodating space, and a rotating ball including a portion accommodated inside the accommodating space of the housing and a remaining portion exposed to an outside of the housing. The rotating ball is rotatable.

One or more example embodiments of the present disclosure provide a brush and a wafer cleaning device that may more effectively remove polishing residues while preventing damage to a wafer.

Further, one or more example embodiments of the present disclosure provide a brush and a wafer cleaning device in which a contact ratio between a nodule of a brush and a wafer may be minimized, thereby minimizing damage to the wafer, and/or causing the nodule to be consumed more slowly, thereby extending the replacement cycle of the brush.

Further, one or more example embodiments of the present disclosure provide for a brush and a wafer cleaning device that may prevent and/or reduce an occurrence of a contaminated nodule from causing the reverse contamination of a wafer during a cleaning process.

Additional aspects may be set forth in part in the description which follows and, in part, may be apparent from the description, and/or may be learned by practice of the presented embodiments.

### BRIEF DESCRIPTION OF THE DRAWINGS

The above and other aspects, features, and advantages of certain embodiments of the present disclosure may be more apparent from the following description taken in conjunction with the accompanying drawings, in which:

FIG. 1 illustrates an example of a wafer polishing device, according to one embodiment of the present disclosure;

FIG. 2 illustrates an example of a part of a cleaner included in the wafer polishing device in FIG. 1, according to one embodiment of the present disclosure;

FIG. 3 is a perspective view for showing an example of a wafer cleaning device, according to one embodiment of the present disclosure;

FIG. 4 is a perspective view for showing an example of a brush, according to one embodiment of the present disclosure;

FIG. 5 is an enlarged view for showing a portion of the brush in FIG. 4, according to one embodiment of the present disclosure;

FIG. 6 is a cross-sectional view for showing an example of how to clean a wafer using the brush, according to one embodiment of the present disclosure’

FIG. 7 is a cross-sectional view for illustrating an example of how a rotating ball is inserted into a body, according to one embodiment of the present disclosure;

FIG. 8 is a cross-sectional view for illustrating an example of how the rotating ball moves toward the body within a housing, according to one embodiment of the present disclosure;

FIGS. 9 and 10 illustrate an example of a wafer cleaning device, according to one embodiment of the present disclosure;

FIGS. 11 and 12 illustrate an example of the brush, according to one embodiment of the present disclosure;

FIGS. 13 to 16 illustrate examples of a brush including various types of nodules, according to some embodiments of the present disclosure;

FIG. 17 is a perspective view for showing an example of a wafer cleaning device, according to one embodiment of the present disclosure;

FIG. 18 is a perspective view for showing an example of a brush included in the wafer cleaning device in FIG. 17, according to one embodiment of the present disclosure; and

FIGS. 19 to 22 illustrate examples of a brush including various types of nodules, according to some embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

As used herein, when an element or layer is referred to as “covering”, “overlapping”, or “surrounding” another element or layer, the element or layer may cover at least a portion of the other element or layer, where the portion may include a fraction of the other element or may include an entirety of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

In the present disclosure, the articles “a” and “an” are intended to include one or more items, and may be used interchangeably with “one or more.” Where only one item is intended, the term “one” or similar language may be used.

As used herein, each of the terms “NH₄OH”, “SiO₂”, “TiO₂”, and the like may refer to a material made of elements included in each of the terms and is not a chemical formula representing a stoichiometric relationship.

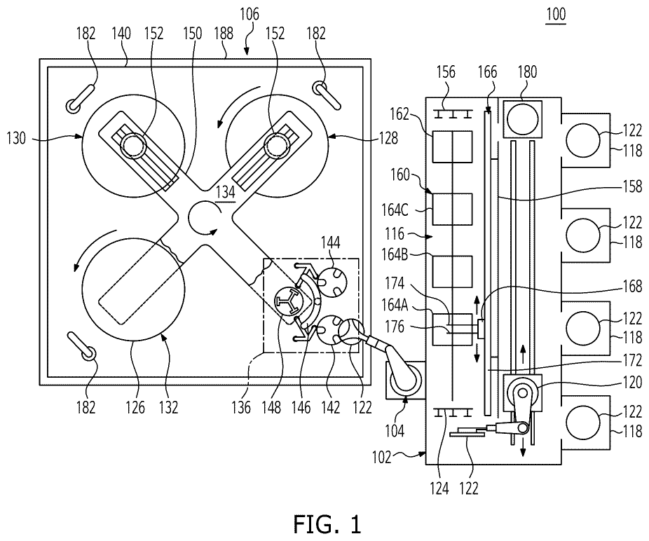

Hereinafter, various embodiments of the present disclosure are described with reference to FIGS. 1 to 22.

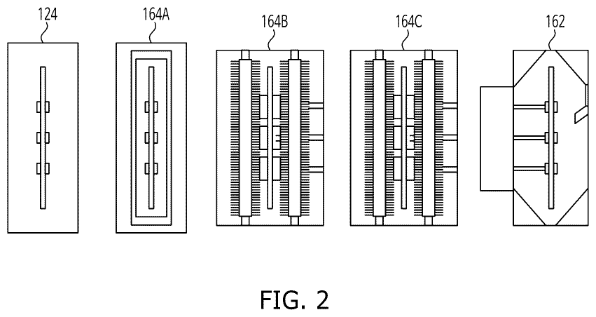

FIG. 1 illustrates an example of a wafer polishing device 100, according to one embodiment of the present disclosure. FIG. 2 illustrates an example of a part of a cleaner 116 included in the wafer polishing device 100 in FIG. 1, according to one embodiment of the present disclosure.

Referring to FIG. 1, the wafer polishing device 100, according to one embodiment of the present disclosure, may include a factory interface 102, a loading robot 104, and a polishing module 106. The loading robot 104 may be placed between the factory interface 102 and the polishing module 106 to move a wafer 122 therebetween.

The factory interface 102 may include a cleaner 116, one or more cassettes 118, and an interface robot 120. The interface robot 120 may move a wafer 122 between the cassette 118 and the cleaner 116 (e.g., an input module 124). For example, the interface robot 120 may move the wafer 122 from one of the one or more cassettes 118 to the input module 124. The loading robot 104 may move the wafer 122 placed in the input module 124 to the polishing module 106.

The polishing module 106 may include one or more chemical-mechanical-polishing stations (e.g., a first chemical-mechanical-polishing station 128, a second chemical-mechanical-polishing station 130, and a third chemical-mechanical-polishing station 132). For example, the polishing module 106 may include the one or more chemical-mechanical-polishing stations 128 to 132 positioned within an environmentally controlled enclosure 188.

As shown in FIG. 1, the polishing module 106 may include the first chemical-mechanical-polishing station 128, the second chemical-mechanical-polishing station 130, and the third chemical-mechanical-polishing station 132. According to one embodiment of the present disclosure, the first chemical-mechanical-polishing station 128 may perform bulk removal of a conductive material of a wafer 122 through a chemical-mechanical-planarization process. In an embodiment, the second chemical-mechanical-polishing station 130 may remove the remaining conductive material from the wafer 122 on which the bulk removal has been carried out by the first chemical-mechanical-polishing station 128. Alternatively or additionally, the third chemical-mechanical-polishing station 132 may perform an additional planarization process on the wafer 122 on which the removal of the remaining conductive material has been carried out by the first chemical-mechanical-polishing station 128.

The polishing module 106 may further include a carousel 134, a transfer station 136, and a control device 182, arranged on a machine base 140.

The carousel 134 may be positioned in the center of the machine base 140. The carousel 134 may include a plurality of arms 150, each of the plurality of arms 150 may support a planarizing head assembly 152. In FIG. 1, two (2) of the plurality of arms 150 have been omitted to ease in illustration of a planarizing surface 126 and the transfer station 136 of the third chemical-mechanical-polishing station 132. The carousel 134 may be designed to be indexable so that the planarizing head assembly 152 may move between the one or more chemical-mechanical-polishing stations 128 to 132 and the transfer station 136.

The transfer station 136 may include an input buffer station 144, an output buffer station 142, a transfer robot 146, and a load cup assembly 148. Wafers 122 may be transferred from the factory interface 102 to the input buffer station 144 by the loading robot 104 to be polished through the polishing module 106. Alternatively or additionally, the wafers 122 polished on at least one side by the polishing module 106 may be transferred from the output buffer station 142 to the factory interface 102 by the loading robot 104.

The transfer robot 146 may be used to transfer wafers 122 between the buffer stations (e.g., the output buffer station 142 and the input buffer station 144) and the load cup assembly 148. The transfer robot 146 may include at least one gripper assembly. For example, the transfer robot 146 may include two (2) gripper assemblies as illustrated in FIG. 1. However, the present disclosure is not limited in this regard. In addition, each gripper assembly may include a pneumatic gripper finger that may hold a wafer 122. According to one embodiment of the present disclosure, the transfer robot 146 may transfer a wafer 122 to be polished from the input buffer station 144 to the load cup assembly 148 while transferring a polished wafer 122 from the load cup assembly 148 to the output buffer station 142.

The control device 182 may be positioned in proximity (e.g., within a certain threshold) to each of the one or more chemical-mechanical-polishing stations 128 to 132 on the machine base 140. The control device 182 may regularly (e.g., periodically, aperiodically, on demand) control a planarizing material provided to the one or more chemical-mechanical-polishing stations 128 to 132 in order to obtain a substantially constant result of planarization.

Referring to FIGS. 1 and 2, the cleaner 116 included in the factory interface 102 may remove polishing residues that may remain after polishing, a polishing fluid flowing from a polished wafer 122, or the like. According to one embodiment of the present disclosure, the cleaner 116 may include the input module 124, a plurality of cleaning modules 160, a drying module 162, a wafer handling module 166, and an output module 156. The input module 124 may be configured as a transfer station between the factory interface 102, the cleaner 116, and the polishing module 106. A wafer 122 that has passed through the plurality of cleaning modules 160 to be fully cleaned may be transferred to the output module 156.

Each of the plurality of cleaning modules 160 may clean the surface of a wafer 122. During the cleaning process, the wafer 122 may move, passing through the plurality of cleaning modules 160, by the wafer handling module 166 arranged around the plurality of cleaning modules 160. According to one embodiment of the present disclosure, the plurality of cleaning modules 160 may include a megasonic module 164A, a first brush module 164B, a second brush module 164C, and a drying module 162. The number, type, order, or the like of the cleaning modules 160 shown in FIGS. 1 and 2 are only an example, and the scope of the present disclosure may not be limited thereto. At least some of the illustrated cleaning modules may be omitted, their order may be changed, and/or cleaning modules not illustrated therein may be added.

The megasonic module 164A may receive a wafer 122 washed with deionized water as needed immediately after it had been fully polished, and may remove large particles through cavitation by megasonic waves.

The first brush module 164B may perform primary scrubbing on the wafer 122 using a brush to remove contaminants for the first time. The second brush module 164C may carry out the second scrubbing on the wafer 122 using a brush to remove contaminants for the second time. The wafer 122 from which contaminants have been removed by the second brush module 164C may be transferred to the drying module 162 by the wafer handling module 166.

The drying module 162 may receive the wafer 122 cleaned by the plurality of cleaning modules 160 and dry the wafer 122. According to one embodiment of the present disclosure, the drying module 162 may dry the wafer 122 using deionized water and/or isopropyl alcohol (IPA). The wafer 122 dried by the drying module 162 may be transferred to the output module 156.

The wafer handling module 166 may include a transfer unit 168 and a rail 172. The transfer unit 168 may move along the rail 172 to transfer a wafer 122 to the input module 124, the megasonic module 164A, the first brush module 164B, the second brush module 164C, and/or the drying module 162. According to one embodiment of the present disclosure, the transfer unit 168 may include grippers (e.g., a first gripper 174 and a second gripper 176) for inserting a wafer 122 into and/or removing a wafer 122 from at least one of the input module 124, the megasonic module 164A, the first brush module 164B, the second brush module 164C, or the drying module 162. In one embodiment, the rail 172 may be coupled to a partition 158 for separating the cassette 118 and the interface robot 120 from the cleaner 116.

A wafer 122 that has been fully dried and moved to the output module 156 may be returned to one of the cassettes 118 by the interface robot 120. According to one embodiment of the present disclosure, the factory interface 102 may further include a metrology device 180 for testing the cleaner 116. The metrology device 180 may include, for example, an optical measuring device. In some embodiments, wafers 122 may be moved to the metrology device 180 by the interface robot 120 and/or the wafer handling module 166 before being returned to the cassette 118. The wafers 122 may be tested within the metrology device 180.

The wafer cleaning device described in the following description of the present disclosure may be applied to at least one of the first brush module 164B or the second brush module 164C described with reference to FIGS. 1 and 2.

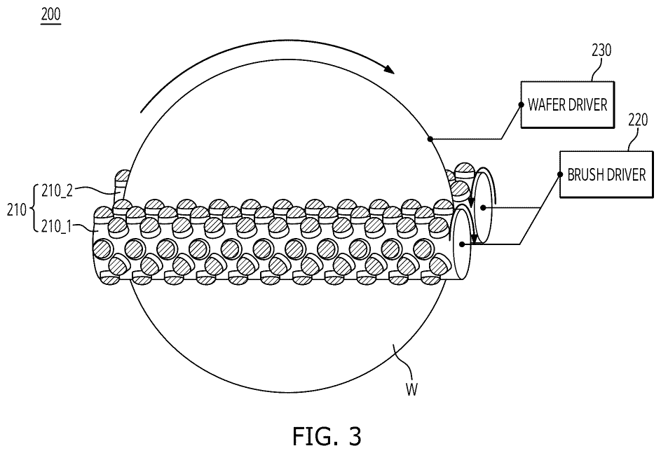

FIG. 3 is a perspective view for showing an example of a wafer cleaning device 200, according to one embodiment of the present disclosure.

Referring to FIG. 3, after a polishing process, such as, but not limited to, a chemical-mechanical-polishing (CMP) process, has been performed on a wafer W, the wafer W may be cleaned by the wafer cleaning device 200. The wafer W of FIG. 3 may include and/or may be similar in many respects to the wafer 122 described above with reference to FIGS. 1 and 2, and may include additional features not mentioned above. Consequently, repeated descriptions of the wafer W described above with reference to FIGS. 1 and 2 may be omitted for the sake of brevity.

According to one embodiment of the present disclosure, the wafer cleaning device 200 may include a brush 210, a brush driver 220, and a wafer driver 230. In some embodiments of the present disclosure, the wafer cleaning device 200 may be referred to as a brush module.

The brush 210 may be placed on a wafer W to be cleaned and may clean the wafer W. For example, the brush 210 may remove particles (e.g., polishing residues) on the surface of the wafer W. According to one embodiment of the present disclosure, the brush 210 may include a plurality of brushes (e.g., a first brush 210_1 and a second brush 210_2). For example, the brush 210 may include the first brush 210_1 disposed on a first surface of the wafer W and the second brush 210_2 disposed on a second surface of the wafer W. In another embodiment, the wafer cleaning device 200 may include only one single brush 210. For example, the wafer cleaning device 200 may include only the first brush 210_1 disposed on the first surface of the wafer W. In such an embodiment, the first surface of the wafer W may be the side on which a polishing process has been performed (e.g., the front side of the wafer W).

The brush driver 220 may be connected to the brush 210 and may rotate and/or move the brush 210. In some embodiments where the brush 210 includes the plurality of first and second brushes 210_1 and 210_2, the brush driver 220 may individually rotate and/or move each of the plurality of first and second brushes 210_1 and 210_2.

According to one embodiment of the present disclosure, the brush driver 220 may rotate the brush 210 around a first rotation axis (e.g., a first rotation axis at the center of each brush 210). In some embodiments where the brush 210 includes the plurality of first and second brushes 210_1 and 210_2, the brush driver 220 may rotate each of the plurality of first and second brushes 210_1 and 210_2 in the same direction, and may rotate at least one of the plurality of first and second brushes 210_1 or 210_2 in a different direction.

In another embodiment, the brush driver 220 may move the brush 210 closer to and/or further away from a wafer W to adjust a degree of contact between the brush 210 and the wafer W.

The wafer driver 230 may be connected to a wafer W, and may rotate and/or move the wafer W. For example, the wafer driver 230 may rotate the wafer W around a second rotation axis (e.g., a second rotation axis at the center of the wafer W). In one embodiment of the present disclosure, the rotation axis of the brush 210 (e.g., the first rotation axis) and the rotation axis of the wafer (e.g., the second rotation axis) may be perpendicular to each other. As the wafer W rotates, various areas of the wafer W may come into contact with the brush 210, thereby allowing the wafer W to be cleaned.

According to one embodiment of the present disclosure, the wafer cleaning device 200 may further include a cleaning solution spray unit including a spraying nozzle. The cleaning solution spray unit may spray a cleaning solution toward a wafer W. The cleaning solution may include, but not be limited to, deionized water (DI water), ammonia water (NH₄OH), hydrofluoric acid (HF), or a mixture of at least some of them. As the cleaning solution is sprayed by the cleaning solution spray unit, the wafer W may be cleaned more effectively.

In one embodiment of the present disclosure, the operation of the wafer cleaning device 200 may be controlled by a controller. For example, the controller may control the brush driver 220, the wafer driver 230, the cleaning solution spray unit, or the like.

The controller may be implemented in hardware, firmware, and/or a combination of hardware and software. In an embodiment, the controller may be physically implemented by analog and/or digital circuits including one or more of a logic gate, an integrated circuit, a microprocessor, a microcontroller, a memory circuit, a passive electronic component, an active electronic component, an optical component, and the like. For example, the controller may be and/or may include a central processing unit (CPU), an application processor (AP), a graphics processing unit (GPU), an accelerated processing unit (APU), a microprocessor, a microcontroller, a digital signal processor (DSP), a field-programmable gate array (FPGA), an application-specific integrated circuit (ASIC), an image signal processor (ISP), a neural processing unit (NPU), a sensor hub processor, a communication processor (CP), an artificial intelligence (AI)-dedicated processor designed to have a hardware structure specified to process an AI model, a general purpose single-chip and/or multi-chip processor, or other programmable logic device, discrete gate or transistor logic, discrete hardware components, or any combination thereof designed to perform the functions described herein. Alternatively or additionally, the controller may include a memory (e.g., volatile memory, such as, but not limited to random access memory (RAM), static RAM (SRAM), or dynamic RAM (DRAM), and/or non-volatile memory, such as, but not limited to, read only memory (ROM), electrically erasable programmable ROM (EEPROM), NAND flash memory, phase-change RAM (PRAM), magnetic RAM (MRAM), resistive RAM (RRAM), ferroelectric RAM (FRAM), magnetic memory, optical memory, or the like) that may store information and/or computer-readable instructions for operation and/or use (e.g., execution) of the wafer cleaning device 200 by the controller. That is, the wafer cleaning device 200 may include a memory storing computer-readable instructions that when executed by one or more controllers (e.g., processors comprising processing circuitry) individually or collectively cause the wafer cleaning device 200 to perform the functions described herein.

Although the wafer W is arranged vertically in FIG. 3, the scope of the present disclosure is not limited thereto. In another embodiment, the wafer W may be positioned horizontally and/or at an acute angle with the ground.

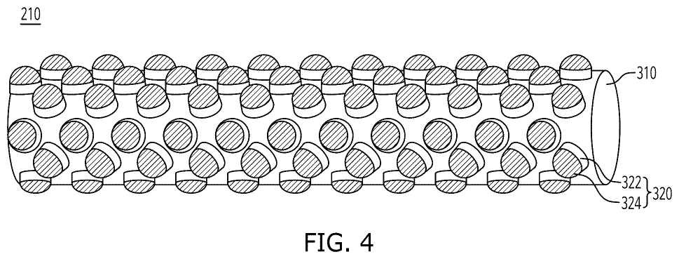

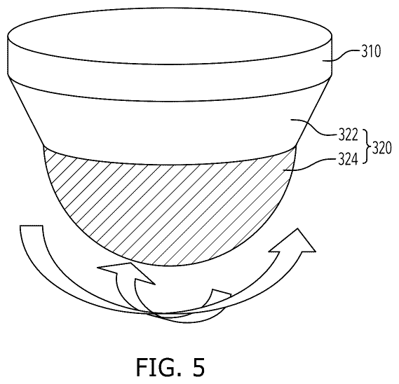

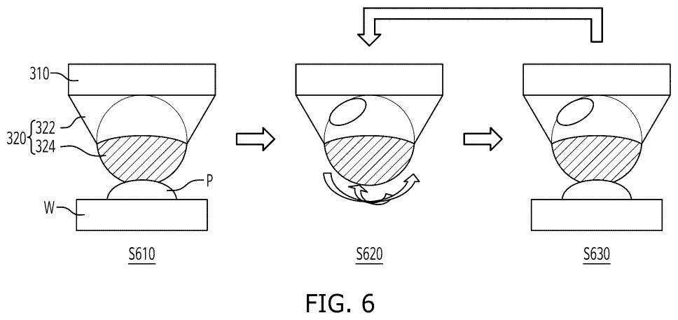

FIG. 4 is a perspective view for showing an example of the brush 210, according to one embodiment of the present disclosure. FIG. 5 is an enlarged view for showing a portion of the brush 210, according to one embodiment of the present disclosure. FIG. 6 is a cross-sectional view for showing an example of how to clean a wafer W using the brush 210, according to one embodiment of the present disclosure.

Referring to FIGS. 4 and 5, the brush 210 may include a body 310 and a plurality of nodules. According to one embodiment of the present disclosure, the body 310 may have a shape elongated in one direction. For example, the body 310 may have a cylindrical shape elongated in one direction.

In various embodiments of the present disclosure, the body 310 may be made of and/or contain diverse materials. For example, the body 310 may contain a ductile material having a relatively high compressibility (e.g., polyvinyl alcohol (PVA), polyurethane (PU), porous materials, materials with a higher compressibility than at least one thereof, or the like), a rigid material having a relatively low compressibility (e.g., silicon dioxide (silica or SiO₂), materials having a lower compressibility than at least one thereof, or the like), a combination thereof, or the like. However, the present disclosure is not limited thereto.

The plurality of nodules may be arranged on at least one side of the body 310 and may protrude outwardly from the body 310. For example, the plurality of nodules may be placed on the outer surface of the body 310 in a cylindrical shape, as shown in FIG. 4. While the brush 210 cleans a wafer, at least one nodule of the plurality of nodules of the brush 210 may come into direct contact with the wafer W. For example, as the brush 210 is rotated by a brush driver (e.g., the brush driver 220 of FIG. 3), the plurality of nodules may be sequentially brought into contact with the wafer W.

The plurality of nodules may include a first nodule type 320 including a housing 322 and a rotating ball 324. The housing 322 may have an open side and an accommodating space therein. For example, a surface of the housing 322 facing the body 310 may be open. That is, the housing 322 may be open toward the outside of the body 310. As another example, the housing 322 may be open toward the outside of the body 310, and may have a truncated cone shape with a diameter that may decrease toward the outside of the body 310.

According to one embodiment of the present disclosure, the housing 322 may contain a material that may be substantially similar to and/or the same as at least a portion of the body 310, such as an outermost layer of the body 310. In one embodiment of the present disclosure, the housing 322 may be formed integrally with at least a portion of the body 310, such as the outermost layer of the body 310.

A part of the rotating ball 324 may be accommodated inside the housing 322, and the other (e.g., the remaining) part thereof may protrude outward from the housing 322. Accordingly, the rotating ball 324 may cover the open side of the housing 322. In an embodiment, the area of the part of the rotating ball 324 protruding outward from the housing 322 may be smaller than the area of the part accommodated inside the housing 322, so that the rotating ball 324 may be prevented from being separated from the housing 322. While the brush 210 cleans a wafer W, the rotating ball 324 may come into direct contact with the wafer W. According to one embodiment of the present disclosure, the rotating ball 324 may have a spherical shape. According to one embodiment of the present disclosure where the rotating ball 324 has a spherical shape, the contact ratio between a wafer W and/or a particle P thereon and a nodule may be minimized. As a result, damage to the wafer W may be minimized, and the nodule may be consumed more slowly, thereby extending the replacement cycle of the brush 210.

The rotating ball 324 may be designed to be rotatable. According to one embodiment of the present disclosure, the rotating ball 324 may be designed to be rotatable in all directions with a portion accommodated inside the housing 322 and the remaining portion protruding outward. However, the present disclosure is not limited thereto. For example, the rotating ball 324 may also be designed to rotate only in a predetermined direction.

Referring to FIG. 6, at operation S610, the rotating ball 324 may come into contact with a wafer W and/or a particle P on the wafer W. At operation S620, with the rotating ball 324 in contact with the wafer W and/or the particle P, the brush 210 may be rotated by a brush driver (e.g., the brush driver 220 of FIG. 3) and/or the wafer W may be rotated by a wafer driver (e.g., the wafer driver 230 of FIG. 3), so that the particle P may be removed from the surface of the wafer W and the rotating ball 324 with the particle P may rotate. As the rotating ball 324 rotates, a contaminated portion of the rotating ball 324 with the particle P may be moved into the housing 322, and an uncontaminated portion of the rotating ball 324 may be exposed to the outside of the housing 322. Then, the wafer W may be cleaned by the uncontaminated portion of the rotating ball 324 at operation S630. According to some embodiments of the present disclosure where, as described above, the brush 210 may be rotatable and the rotating ball 324 is included, as the contaminated portion of the rotating ball 324 moves continuously, the reverse contamination of the wafer W by a contaminated nodule may be minimized.

In various embodiments of the present disclosure, the rotating ball 324 may be made of and/or contain diverse materials. For example, the rotating ball 324 may contain a ductile material (e.g., polyvinyl alcohol (PVA), polyurethane (PU), porous materials, or the like), a rigid material (e.g., silicon dioxide (SiO₂), or the like), and/or a material having a relatively high thermal conductivity (e.g., polystyrene (PS), polyacrylamide (PAM), polyethylene (PE), polyphenylene oxide (PPO), polyvinylidene chloride (PVDC), materials having a higher thermal conductivity than at least one thereof, or the like). However, the present disclosure is not limited thereto.

According to some embodiments of the present disclosure where the rotating ball 324 contains a material having a relatively high thermal conductivity, frictional heat resulting from friction between a wafer W and/or a particle P thereon and the brush 210 may be absorbed by the rotating ball 324. Consequently, a risk of the wafer W being damaged due to the frictional heat during a cleaning process may be reduced.

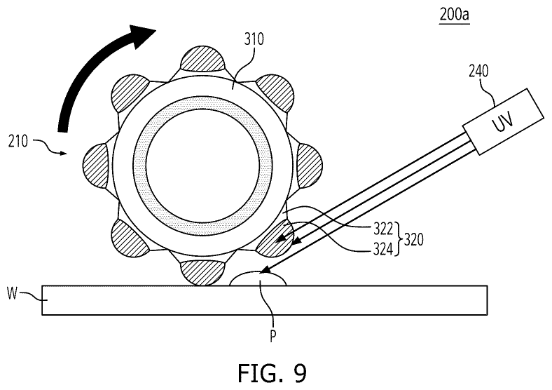

According to some embodiments of the present disclosure, the rotating ball 324 may contain a photocatalyst material and/or a magnetic material. An embodiment of the present disclosure where the rotating ball 324 contains a photocatalyst material and/or a magnetic material is described with reference to FIGS. 9 to 12.

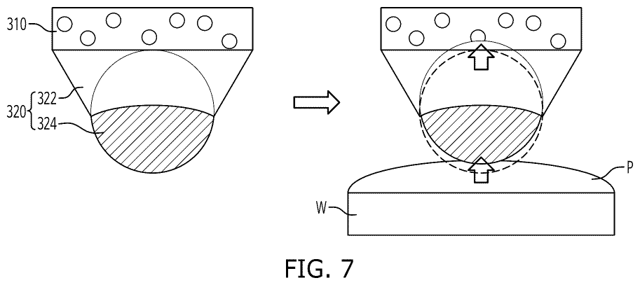

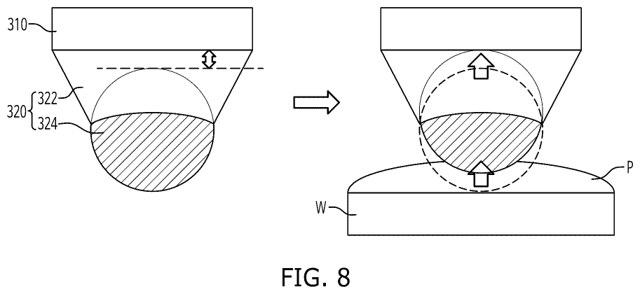

FIG. 7 is a cross-sectional view for illustrating an example of how the rotating ball 324 is inserted into the body 310, according to one embodiment of the present disclosure. FIG. 8 is a cross-sectional view for illustrating an example of how the rotating ball 324 moves toward the body 310 within the housing 322, according to one embodiment of the present disclosure.

During a cleaning process, the brush 210 may apply pressure to a wafer W. For example, the brush 210 may rotate to remove particles P on the wafer W while the plurality of nodules of the brush 210 are in contact with the wafer W, and, during this process, pressure may be applied to the wafer W. When excessive pressure is applied to the wafer W during the cleaning process, the wafer W may be damaged as the plurality of nodules and/or the particles P in contact with the nodules rub against the wafer W. According to some embodiments of the present disclosure, the brush 210 may be designed to avoid and/or reduce a probability of a wafer W from being excessively pressurized during a cleaning process.

According to one embodiment, as illustrated in FIG. 7, the body 310 of the brush 210 may contain a material that may be compressed when pressure is applied. For example, the body 310 may contain, but be not limited to, a ductile material having a relatively high compressibility (e.g., polyvinyl alcohol (PVA), polyurethane (PU), porous materials, materials having a higher compressibility than at least one thereof, or the like). According to such an embodiment, when pressure is applied into the brush 210 by a counterforce to the force of the brush 210 pressing a wafer W and/or a particle P thereon during a cleaning process, the rotating ball 324 may be inserted into the body 310. As a result, the brush 210 may prevent and/or reduce excessive pressure from being applied to the wafer W, thereby minimizing damage to the wafer W.

In another embodiment, as illustrated in FIG. 8, the rotating ball 324 may be designed to move closer to and/or away from the body 310 within the housing 322. For example, when the rotating ball 324 of the first nodule type 320 is on an outermost side of the housing 322, the rotating ball 324 may not come into contact with the outer surface of the body 310. That is, when the rotating ball 324 is on the outermost side of the housing 322, there may be an empty space between the rotating ball 324 and the body 310. According to such an embodiment, when pressure is applied toward the brush 210 by a counterforce of the force of the brush 210 pressing a wafer W during a cleaning process, the rotating ball 324 may move closer to the body 310 within the housing 322. For example, the rotating ball 324 may move toward the body 310 within the housing 322 and come into contact with the outer surface of the body 310. As a result, the brush 210 may prevent and/or reduce excessive pressure from being applied to the wafer W, thereby minimizing damage to the wafer W.

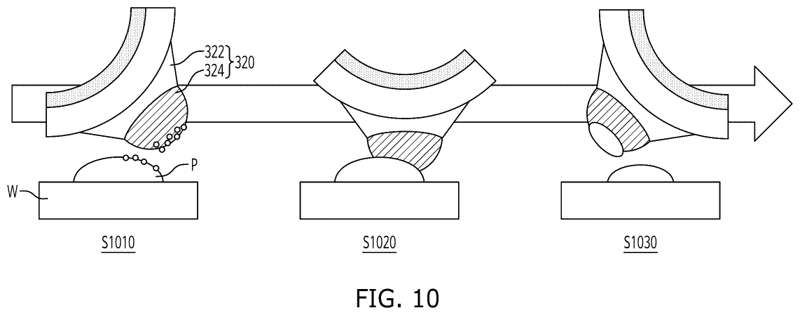

FIGS. 9 and 10 illustrate an example of the wafer cleaning device 200a, according to one embodiment of the present disclosure. The wafer cleaning device 200a may include and/or may be similar in many respects to the wafer cleaning device 200 described above with reference to FIGS. 1 to 8, and may include additional features not mentioned above. Consequently, repeated descriptions of the wafer cleaning device 200a described above with reference to FIGS. 1 to 8 may be omitted for the sake of brevity.

Referring to FIG. 9, the wafer cleaning device 200a, according to one embodiment, may further include a light source unit 240. The light source unit 240 may radiate ultraviolet (UV) rays to the wafer W and the brush 210. For example, the light source unit 240 may radiate ultraviolet rays to particles P on the wafer W and the plurality of nodules of the brush 210 such as, for example, the rotating ball 324 of the first nodule type 320.

In one embodiment, the plurality of nodules of the brush 210 may contain a photocatalyst material. For example, the rotating ball 324 included in the first nodule type 320 may contain a photocatalyst material that may increase the reactivity of the rotating ball 324 when light (e.g., UV light) is radiated thereto. As another example, the rotating ball 324 may include a radical-based photocatalyst, such as, but not limited to, titanium dioxide (TiO₂), that may increase reactivity of the rotating ball 324 by inducing the formation of radicals when ultraviolet light is radiated thereto. As yet another example, the rotating ball 324 may be and/or may include, but not limited to, a polymer containing a radical-based photocatalyst, such as, for example, polyurethane (PU) containing titanium dioxide (TiO₂).

According to such an embodiment, the wafer cleaning device 200a may clean a wafer W more effectively.

Referring to FIG. 10, at operation S1010, before the first nodule type 320 comes into contact with a particle P on the wafer W, as ultraviolet rays are radiated on the rotating ball 324 and the particle P on the wafer W, radicals may be formed, thereby increasing the reactivity of the rotating ball 324 and the particle P. Then, at operation S1020, as the brush 210 rotates, the rotating ball 324 of the first nodule type 320 may come into contact with the particle P. Here, the particle P may be effectively adsorbed to the rotating ball 324 as a result of the increased reactivity of the rotating ball 324 and the particle P. Accordingly, the particle P may be removed more effectively from the wafer W at operation S1030.

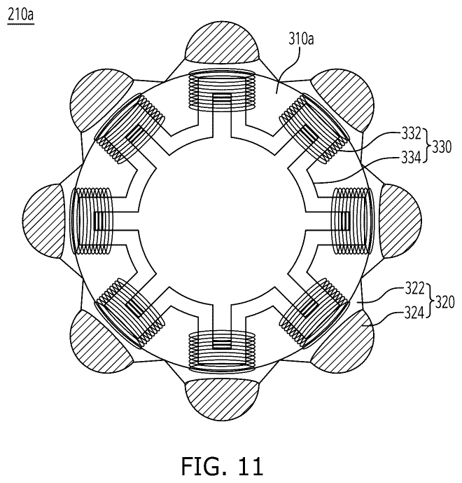

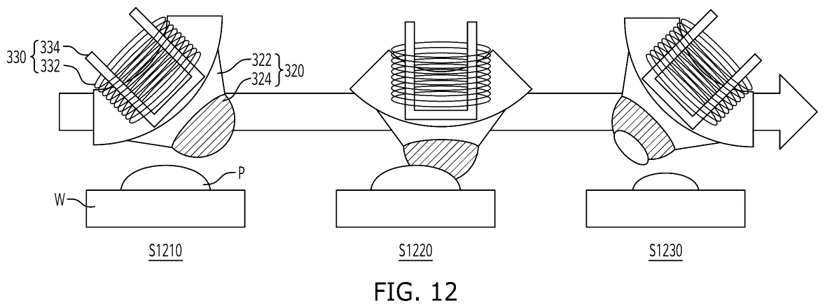

FIGS. 11 and 12 illustrate an example of the brush 210a according to one embodiment of the present disclosure. The brush 210a may include and/or may be similar in many respects to the brush 210 described above with reference to FIGS. 1 to 10, and may include additional features not mentioned above. Furthermore, a body 310a may include and/or may be similar in many respects to the body 310 described above with reference to FIGS. 1 to 10, and may include additional features not mentioned above. Consequently, repeated descriptions of the brush 210a and the body 310a described above with reference to FIGS. 1 to 10 may be omitted for the sake of brevity.

Referring to FIG. 11, the brush 210a, according to one embodiment, may further include an electromagnet 330 including a solenoid coil 332 and an iron core 334 inside the body 310a. The solenoid coil 332 may be arranged inside the body 310a. For example, a plurality of solenoid coils 332 may be respectively arranged at a position corresponding to each of the plurality of nodules, such as the first nodule type 320, inside the body 310a. As another example, a winding axis of each of the plurality of solenoid coils 332 inside the body 310a may be parallel to the direction in which each nodule of the plurality of nodules, such as the first nodule type 320 protrudes (e.g., the radial direction of the body 310a). In addition, at least a portion of the iron core 334 inside the body 310a may be inserted into the solenoid coil 332.

In an embodiment, a wafer cleaning device including the brush 210a with the electromagnet 330 may further include a power supply. The power supply may supply and/or stop (e.g., prevent from being supplied) power to the iron core 334 disposed inside the body 310a. Accordingly, current may flow and/or may not flow through the iron core 334 inside the body 310a. When current flows through the iron core 334 inside the body 310a, a magnetic field may be formed by the electromagnet 330. Alternatively or additionally, when current does not flow through the iron core 334 inside the body 310a, the magnetic field may disappear (e.g., may not be formed). In one embodiment, the power supply may repeat the operation of supplying and/or stopping power to the iron core 334. That is, the power supply may supply and/or stop power to the iron core 334 in a periodic, aperiodic, and/or on demand manner. As a result, a magnetic field may be formed and/or may disappear repeatedly around the electromagnet 330 of the brush 210a.

The rotating ball 324 included in the first nodule type 320 of the brush 210a may contain a magnetic material having a hardness that may change when exposed to a magnetic field. For example, the rotating ball 324 may contain a magnetic material whose hardness may increase as a magnetic field is applied. As another example, the rotating ball 324 may include a variable stiffness polymer, which may be magnetically responsive and/or may contain magnetic microparticles dispersed in a polymer matrix, magnetorheological elastomer (MRE) containing magnetic microparticles dispersed in an elastomer matrix, or the like.

According to such an embodiment, the brush 210a may remove a particle P more effectively while reducing damage to a wafer W. Referring to FIG. 12, the power supply may supply power to the iron core 334 until the rotating ball 324 comes into contact with the particle P on the wafer W at operations S1210 and S1220. Accordingly, a magnetic field may be formed around the electromagnet 330 of the brush 210a, and the hardness of the rotating ball 324 containing a magnetic material may increase. The rotating ball 324 with the increased hardness may remove the particle P on the wafer W. In addition, after the rotating ball 324 has come into contact with the particle P on the wafer W at operations S1220 and S1230, the power supply may stop supplying power to the iron core 334. Consequently, the magnetic field formed around the electromagnet 330 of the brush 210a may disappear, and the hardness of the rotating ball 324 containing the magnetic material may decrease. As the hardness of the rotating ball 324 decreases, damage to the wafer W due to friction between the rotating ball 324 (and/or the particle P in contact with the rotating ball 324) and the wafer W may be minimized.

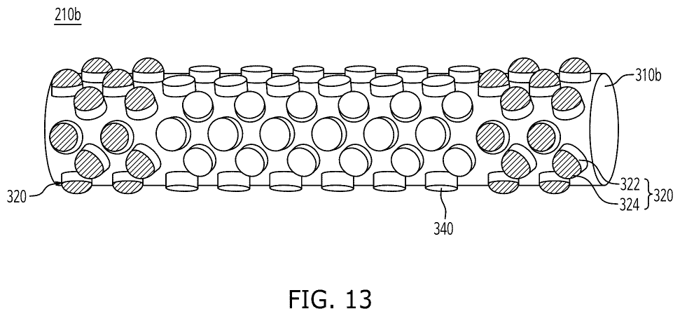

FIGS. 13 to 16 illustrate examples of brushes 210b, 210c, 210d, and 210e, respectively, which include various types of nodules, according to some embodiments of the present disclosure. The brushes 210b, 210c, 210d, and 210e may include and/or may be similar in many respects to the brushes 210 and 210a described above with reference to FIGS. 1 to 12, and may include additional features not mentioned above. Consequently, repeated descriptions of the brushes 210b, 210c, 210d, and 210e described above with reference to FIGS. 1 to 12 may be omitted for the sake of brevity.

According to one embodiment, the brushes 210b, 210c, 210d, and 210e may include various types of nodules. For example, the brushes 210b, 210c, 210d, and 210e may include the first nodule type 320 and a second nodule type 340. The first nodule type 320 may include the housing 322 and the rotating ball 324. The second nodule type 340 may have a cylindrical shape. For example, the second nodule type 340 may have a cylindrical shape extending outward from the outer surface of the body 310a in a cylindrical shape. According to one embodiment, the diameter of the rotating ball 324 included in the first nodule type 320 may be substantially similar to and/or the same as the height of the second nodule type 340.

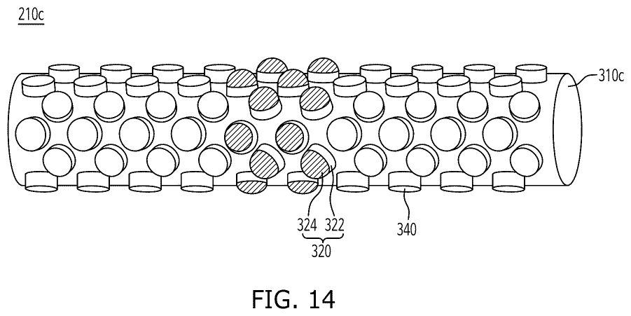

The first nodule type 320 and the second nodule type 340 on the brushes 210b, 210c, 210d, and 210e may be arranged in various manners. According to some embodiments, the first nodule type 320 may be disposed on an edge area and/or a center area along a length direction of the body (e.g., bodies 310b, 310c, 310d, and 310e) on the outer surface of the body. For example, in brush 210b as shown in FIG. 13, a plurality of nodules of the first nodule type 320 may be arranged on both edge areas along the length direction of the body 310b on the outer surface of the body 310b, and a plurality of nodules of the second nodule type 340 may be placed on a center area between the two (2) edge areas. For another example, in brush 210c as illustrated in FIG. 14, a plurality of nodules of the first nodule type 320 may be arranged on a center area along the length direction of the body 310c on the outer surface of the body 310c, and a plurality of nodules of the second nodule type 340 may be positioned on both edge areas.

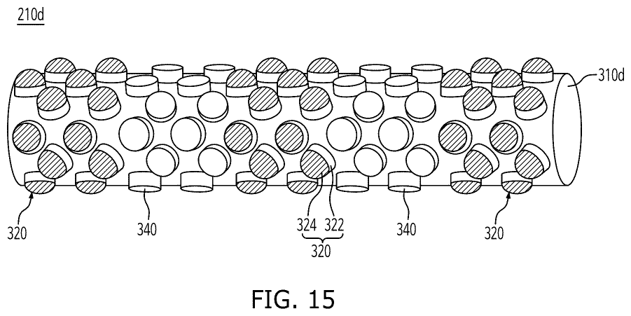

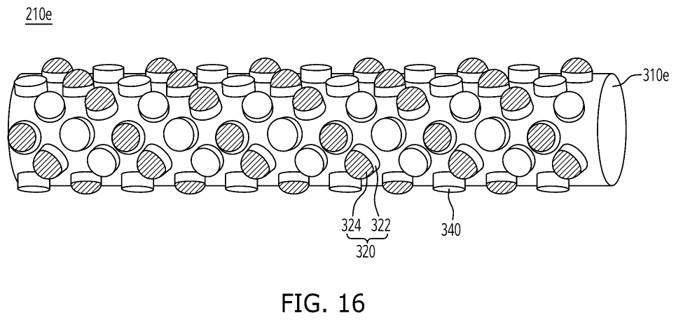

According to some embodiments, the first nodule type 320 and the second nodule type 340 may be arranged alternately. For example, in brush 210d as shown in FIG. 15, a plurality of nodules of the first nodule type 320 may be arranged on both edge areas and a center area along the length direction of the body 310d on the outer surface of the body 310d, and a plurality of nodules of the second nodule type 340 may be placed on areas between the edge areas and the center area. As another example, in brush 210e as illustrated in FIG. 16, a plurality of nodules of the first nodule type 320 and a plurality of nodules of the second nodule type 340 may be respectively arranged on the outer surface of the body 310e along spiral paths adjacent to each other.

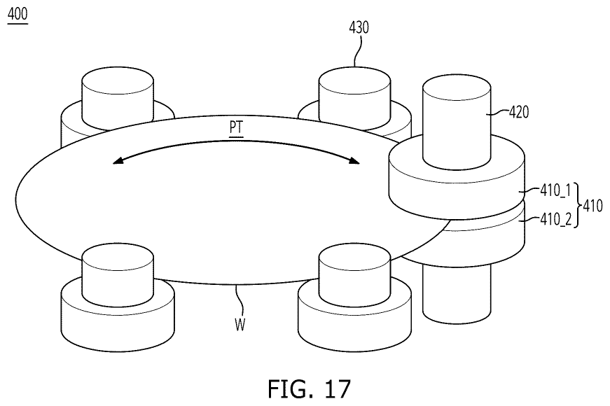

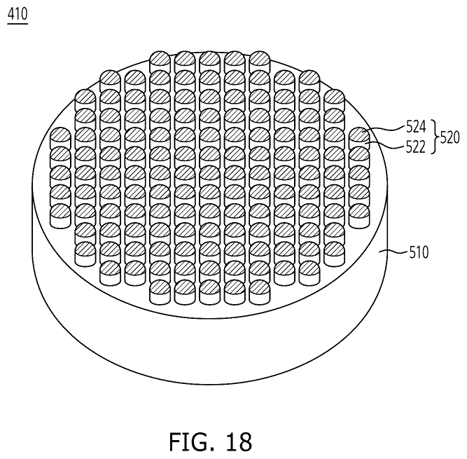

FIG. 17 is a perspective view for showing an example of a wafer cleaning device 400, according to one embodiment of the present disclosure. FIG. 18 is a perspective view for showing an example of a brush 410, according to one embodiment of the present disclosure. The wafer cleaning device 400 may include and/or may be similar in many respects to the wafer cleaning devices 200 and 200a described above with reference to FIGS. 1 to 16, and may include additional features not mentioned above. Furthermore, the brush 410 may include and/or may be similar in many respects to the brushes 210, 210a, 210b, 210c, 210d, and 210e described above with reference to FIGS. 1 to 16, and may include additional features not mentioned above. Consequently, repeated descriptions of the wafer cleaning device 400 and the brush 410 described above with reference to FIGS. 1 to 16 may be omitted for the sake of brevity.

Referring to FIG. 17, the wafer cleaning device 400 may include the brush 410, a brush driver 420, and a wafer driver 430. In some embodiments, the wafer cleaning device 400 may be referred to as a brush module.

The brush 410 may be placed on a wafer W to be cleaned, and may clean wafer W. FIG. 17 shows the wafer cleaning device including a plurality of brushes (e.g. a first brush 410_1 and a second brush 410_2), however, the present disclosure is not limited thereto. According to another embodiment, the wafer cleaning device 400 may include only one single brush 410_1.

The brush driver 420 may be connected to the brush 410, and may rotate and/or move the brush 410. In some embodiments where the brush 410 includes the plurality of first and second brushes 410_1 and 410_2, the brush driver 420 may individually rotate and/or move each of the plurality of first and second brushes 410_1 and 410_2.

According to one embodiment of the present disclosure, the brush driver 420 may rotate the brush 410 around a first rotation axis (e.g., a first rotation axis at the center of each brush 410). In some embodiments where the brush 410 includes the plurality of first and second brushes 410_1 and 4102, the brush driver 420 may rotate each of the plurality of first and second brushes 410_1 and 410_2 in the same direction, and may rotate at least one of the plurality of first and second brushes 410_1 or 410_2 in a different direction.

In another embodiment, the brush driver 420 may move the brush 410 on a wafer W along a predefined path PT. The predefined path PT may be a straight and/or a curved path across the wafer W, however, the present disclosure is not limited thereto.

The wafer driver 430 may be connected to a wafer W, and may rotate and/or move the wafer W. For example, the wafer driver 430 may rotate the wafer W around a second rotation axis (e.g., a second rotation axis at the center of the wafer W). In one embodiment of the present disclosure, the rotation axis of the brush 410 (e.g., the first rotation axis) and the rotation axis of the wafer (e.g., the second rotation axis) may be parallel to each other.

Referring to FIG. 18, the brush 410 may include a body 510 and a plurality of nodules. According to one embodiment, the body 510 may have a disc shape. As used herein, the disc shape may refer to, for example, the shape of a cylinder with a comparatively short distance between its two (2) sides when compared to its diameter. The plurality of nodules may be arranged on a side of the body 510 and may protrude outward from the side of the body 510. For example, the plurality of nodules may be placed on at least one of both circular surfaces of the body 510 having a disk shape, as shown in FIG. 18. The plurality of nodules may include a first nodule type 520 including a housing 522 and a rotating ball 524. The first nodule type 520 may include and/or may be similar in many respects to the first nodule type 320 described above with reference to FIGS. 1 to 16, and may include additional features not mentioned above. Furthermore, the housing 522 and the rotating ball 524 may include and/or may be similar in many respects to the housing 322 and the rotating ball 324, respectively, described above with reference to FIGS. 1 to 16, and may include additional features not mentioned above. Consequently, repeated descriptions of the first nodule type 520, the housing 522, and the rotating ball 524 described above with reference to FIGS. 1 to 16 may be omitted for the sake of brevity.

According to some embodiments where the body 510 has a disk shape, a relatively large number of nodules may come in contact with a wafer W simultaneously, thereby allowing the wafer W to be cleaned more quickly.

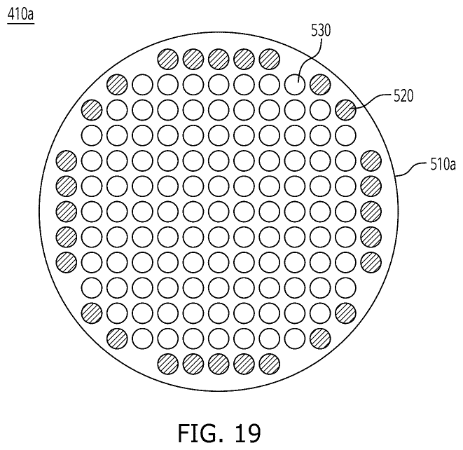

FIGS. 19 to 22 illustrate examples of brushes 410a, 410b, 410c, and 410d including various types of nodules, according to some embodiments of the present disclosure. The brushes 410a, 410b, 410c, and 410d may include and/or may be similar in many respects to the brushes 210, 210a, 210b, 210c, 210d, 210e, and 410 described above with reference to FIGS. 1 to 18, and may include additional features not mentioned above. Consequently, repeated descriptions of the brushes 410a, 410b, 410c, and 410d described above with reference to FIGS. 1 to 18 may be omitted for the sake of brevity.

According to one embodiment, the brushes 410a, 410b, 410c, and 410d may include various types of nodules. For example, the brushes 410a, 410b, 410c, and 410d may include at least one of the first nodule type 520 or the second nodule type 530. The first nodule type 520 may include the housing 522 and the rotating ball 524. The second nodule type 530 may have a cylindrical shape. For example, the second nodule type 530 may have a cylindrical shape extending outward from a side of the body (e.g., bodies 510a, 510b, 510c, and 510d) having a disk shape. According to one embodiment, the diameter of the rotating ball 524 included in the first nodule type 520 may be substantially similar to and/or the same as the height of the second nodule type 530.

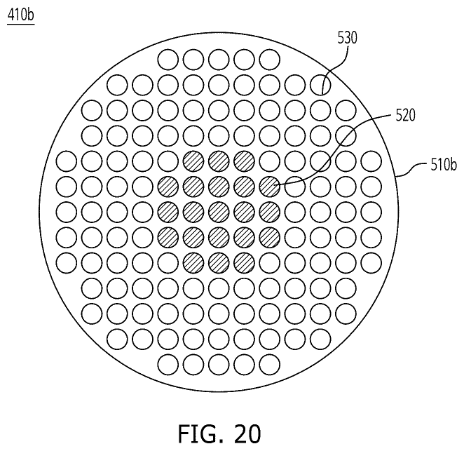

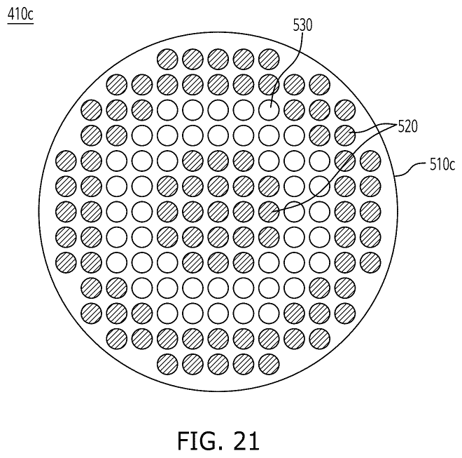

The first nodule type 520 and the second nodule type 530 on the brushes 410a, 410b, 410c, and 410d may be arranged in various manners. According to some embodiments, the first nodule type 520 may be positioned on an edge area and/or a center area of a circular surface of the body (e.g., bodies 510a, 510b, 510c, and 510d). For example, in brush 410a as illustrated in FIG. 19, a plurality of nodules of the first nodule type 520 may be placed on an edge area of a circular surface of the body 510a, and a plurality of nodules of the second nodule type 530 may be placed on a center area surrounded by the edge area. As another example, in brush 410b as illustrated in FIG. 20, a plurality of nodules of the first nodule type 520 may be disposed on a center area of a circular surface of the body 510b, and a plurality of nodules of the second nodule type 530 may be disposed on an edge area surrounding the center area. As yet another example, in brush 410c as shown in FIG. 21, a plurality of nodules of the first nodule type 520 may be arranged on an edge area and a center area of a circular surface of the body 510c, and a plurality of nodules of the second nodule type 530 may be arranged on an area between the edge area and the center area.

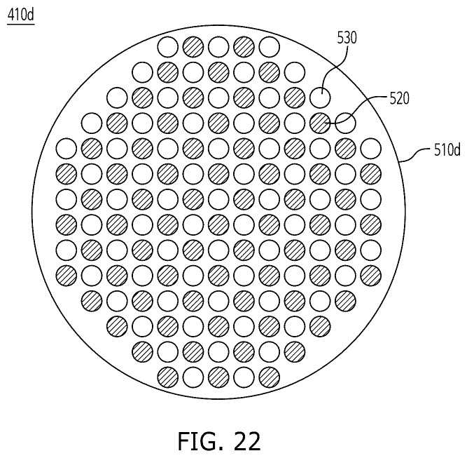

According to some embodiments, the first nodule type 520 and the second nodule type 530 may be positioned alternately. For example, in brush 410d as illustrated in FIG. 22, a plurality of nodules of the first nodule type 520 and a plurality of nodules of the second nodule type 530 may be alternately arranged on a circular surface of the body 510d.

Embodiments of the present disclosure have been disclosed by way of example, and a person having ordinary skill in the present disclosure is to understand that various modifications, changes, and additions may be made within the spirit and the scope of the present disclosure and such modifications, changes, and additions fall within the scope of the patent claims.

A person having ordinary skill in the technical field to which the present disclosure belongs is to understand that, because a range of substitutions, modifications, and changes may be made within the technology of the present disclosure, the present disclosure is not limited to the above-described embodiments and the attached drawings.

What is claimed is:

1. A brush, comprising:
a body; and
a plurality of nodules disposed on at least one surface of the body and at least partially protruding outward from the body,
wherein the plurality of nodules comprise a plurality of first nodules,
wherein each nodule of the plurality of first nodules comprises:
a housing comprising an open side and an accommodating space; and
a rotating ball comprising a portion accommodated inside the accommodating space of the housing and a remaining portion exposed to an outside of the housing, and
wherein the rotating ball is rotatable.

2. The brush of claim 1, wherein the housing has a truncated cone shape with a diameter that decreases toward an outside of the body, and
wherein the open side of the housing faces the body.

3. The brush of claim 1, wherein the body comprises a material configured to compress based on a pressure being applied.

4. The brush of claim 1, wherein the rotating ball is configured to move within the housing at least one of closer to the body or away from the body.

5. The brush of claim 1, wherein the rotating ball comprises a photocatalyst material configured to increase a reactivity of the rotating ball based on light being radiated on the rotating ball.

6. The brush of claim 1, further comprising:
a solenoid coil disposed inside the body and having a winding axis parallel to a direction in which the plurality of nodules at least partially protrude; and
an iron core having at least one portion disposed inside the solenoid coil,
wherein the rotating ball comprises a magnetic material configured to change hardness based on being exposed to a magnetic field.

7. The brush of claim 1, wherein the plurality of nodules further comprise a plurality of second nodules having a cylindrical shape.

8. The brush of claim 7, wherein a diameter of the rotating ball of each nodule of the plurality of first nodules is equal to a height of each nodule of the plurality of second nodules.

9. The brush of claim 1, wherein the body has a first cylindrical shape elongated in a first direction, and
wherein the plurality of nodules are disposed on an outer surface of the body.

10. The brush of claim 9, wherein the plurality of nodules further comprise a plurality of second nodules having a second cylindrical shape, and
wherein the plurality of first nodules are disposed on at least one of an edge area or a center area along the first direction on the outer surface of the body.

11. The brush of claim 9, wherein the plurality of nodules further comprise a plurality of second nodules having a second cylindrical shape,
wherein the plurality of first nodules are disposed on a center area and an edge area along the first direction on the outer surface of the body, and
wherein the plurality of second nodules are disposed between the center area and the edge area on the outer surface of the body.

12. The brush of claim 9, wherein the plurality of nodules further comprise a plurality of second nodules having a second cylindrical shape, and
wherein the plurality of first nodules and the plurality of second nodules are respectively disposed on the outer surface of the body along spiral paths adjacent to each other.

13. The brush of claim 1, wherein the body has a disk shape, and
wherein the plurality of nodules are disposed on one surface of the body.

14. The brush of claim 13, wherein the plurality of nodules further comprise a plurality of second nodules having a cylindrical shape, and
wherein the plurality of first nodules are disposed on at least one of an edge area or a center area of a side of the body.

15. The brush of claim 13, wherein the plurality of nodules further comprise a plurality of second nodules having a cylindrical shape,
wherein the plurality of first nodules are disposed on a center area and an edge area of a side of the body, and
wherein the plurality of second nodules are disposed between the center area and the edge area of the side of the body.

16. The brush of claim 13, wherein the plurality of nodules further comprise a plurality of second nodules having a cylindrical shape, and
wherein the plurality of first nodules and the plurality of second nodules are alternately disposed on a bottom surface of the body.

17. The brush of claim 1, wherein at least one portion of the body and the housing are formed integrally.

18. A wafer cleaning device, comprising:
a brush;
a brush driver configured to rotate the brush around a first rotation axis; and
a wafer driver configured to rotate a wafer to be cleaned around a second rotation axis perpendicular to the first rotation axis,
wherein the brush comprises:
a cylindrical body elongated in a direction parallel to the first rotation axis; and
a plurality of nodules disposed on an outer surface of the cylindrical body and at least partially protruding outward from the cylindrical body,
wherein each nodule of the plurality of nodules comprises:
a housing comprising an open side and an accommodating space; and
a rotating ball comprising a portion accommodated inside the accommodating space of the housing and a remaining portion exposed to the outside of the housing, and
wherein the rotating ball is rotatable.

19. The wafer cleaning device of claim 18, further comprising:
a light source unit configured to radiate ultraviolet rays onto the wafer and the plurality of nodules,
wherein the rotating ball comprises a photocatalyst material configured to increase a reactivity of the rotating ball based on being exposed to light.

20. A wafer cleaning device, comprising:
a brush;
a brush driver configured to rotate the brush around a first rotation axis; and
a wafer driver configured to rotate a wafer to be cleaned around a second rotation axis parallel to the first rotation axis,
wherein the brush comprises:
a disc-shaped body; and
a plurality of nodules disposed on one side of the disc-shaped body and at least partially protruding outward from a side of the disc-shaped body, and
wherein each nodule of the plurality of nodules comprises:
a housing comprising an open side and an accommodating space; and
a rotating ball comprising a portion accommodated inside the accommodating space of the housing and a remaining portion exposed to an outside of the housing, and
wherein the rotating ball is rotatable.
